(19) United States
(12) Patent Application Publication
(10) Pub. No.: US 2025/0351314 A1
(43) Pub. Date: Nov. 13, 2025

(54) COOLING SYSTEM FOR POWER ELECTRONIC SYSTEMS

(71) Applicant: Caterpillar Inc., Peoria, IL (US)

(72) Inventors: Prashanth PADMANABHAN, Bangalore (IN); Tushar Athale, Bangalore (IN); Basheer Qattum, Peoria, IL (US); Dustin Craig Selvey, Eureka, IL (US); Prathamesh Shivapuri, Belagavi (IN); Nitin Pandey, Bhilai (IN)

(73) Assignee: Caterpillar Inc., Peoria, IL (US)

(21) Appl. No.: 18/659,804

(22) Filed: May 9, 2024

(51) Int. Cl. H05K 7/20; B60K 11/04

(52) U.S. Cl. CPC H05K 7/20927; H05K 7/20272; H05K 7/20909; B60K 11/04

(57) ABSTRACT

Disclosed is a cooling system for a power electronic system comprising a heat exchanger, coolant lines disposed within the heat exchanger and throughout the power electronic system, a pump configured to distribute coolant throughout the coolant lines, a fan configured for air intake through the heat exchanger to cool the coolant lines, and a duct assembly configured to direct the air intake from the fan towards the power electronic system.

### TECHNICAL FIELD

The present invention relates generally to cooling systems for electronic components, and more particularly to a cooling systems for use with power electronic systems.

### BACKGROUND

Electronic components, particularly those involved in power conversion and charging processes, generate significant amounts of heat during operation. Effective management of this heat is crucial to maintain the reliability, efficiency, and longevity of these components. Traditional cooling methods, including air and liquid cooling systems, have been employed to address these thermal management challenges. However, these solutions often require substantial space for implementation, involving large radiators, fans, or pumps, which may not be feasible in compact charging systems.

In the context of charging systems, such as those used for electric vehicles, portable electronics, or industrial machinery, the demand for increased portability has intensified the need for a cooling solution that can operate efficiently within a confined space. The integration of cooling systems within these compact enclosures poses significant design challenges, including but not limited to, the efficient use of space, the ability to provide adequate cooling to critical components, and the maintenance of the system's overall compactness.

Moreover, the environmental conditions within compact enclosures can exacerbate the cooling challenge. Restricted airflow, increased ambient temperatures, and the proximity of heat-generating components can lead to thermal accumulation, further impacting the performance and reliability of the system.

Existing solutions often compromise either the efficiency of cooling or the compactness of the system design, leading to overheated components, reduced operational lifespans, and increased physical footprints of the charging systems. Thus, there is need for an innovative cooling solution that addresses these challenges by providing efficient thermal management within the spatial constraints of compact charging system enclosures.

Others have attempted to develop systems for cooling electronic systems but have not fully addressed issues like space constraints, cooling efficiency, and ambient temperature control in a container. For instance, WO 2014/190688 (hereinafter referred to as “the WO reference”) discloses a traction system cooling unit with a water-cooling loop for a power module and an oil cooling loop for a transformer. However, while the WO reference provides a dual-channel cross-flow radiator with air flow that absorbs the heat of the oil, the WO reference fails to disclose recirculating the air for cooling a transformer. Thus, there remains a need for a single cooling system that pumps coolant and air for cooling a transformer.

It can therefore be seen that a need exists for cooling systems with efficient thermal energy management.

### SUMMARY

In accordance with one aspect of the disclosure, a cooling system for a power electronic system is disclosed. The cooling system comprises a heat exchanger, coolant lines disposed within the heat exchanger and throughout the power electronic system, a pump configured to distribute coolant throughout the coolant lines, a fan configured for air intake through the heat exchanger to cool the coolant lines, and a duct assembly configured to direct the air intake from the fan towards the power electronic system.

In accordance with another aspect of the disclosure, an energy container for housing a power electronic system is disclosed. The energy container comprises: a container; a power electronic module (PEM); a plurality of transformers; and a cooling system including: a heat exchanger; coolant lines disposed within the heat exchanger and throughout the power electronic system; a pump configured to distribute coolant throughout the coolant lines; a fan configured for air intake through the heat exchanger to cool the coolant lines; and a duct assembly configured to direct the air intake from the fan towards the plurality of transformers.

In accordance with another aspect of the disclosure, a method for cooling a power electronic system within an energy container is disclosed. The method comprises: providing a power electronic module (PEM) housed within the energy container, the PEM including a plurality of transformers, each transformer comprising a plurality of cores; circulating coolant through a cooling system integrated with the PEM, the cooling system including a heat exchanger, a duct assembly, a pump, and coolant lines disposed within the heat exchanger and throughout the PEM, the pump is operated to distribute a coolant throughout the coolant lines; drawing air into the duct assembly through a louver using a fan; and directing intake of air from the fan through the duct assembly towards the plurality of transformers.

These and other aspects and features of the present disclosure will be better understood upon reading the following detailed description when read in conjunction with the accompanying drawings.

### BRIEF DESCRIPTION OF THE DRAWINGS

FIG. 1 is a perspective view is an energy container comprising a Power Electronic (PE) system, according to an embodiment of the present disclosure.

FIG. 2 is a perspective view of the PE system, according to an embodiment of the present disclosure.

FIG. 3 is a cross-section schematic of the PE system taken along line 3-3 of FIG. 2, according to an embodiment of the present disclosure.

FIG. 4 is a perspective view of a portion of the cooling system of the PE system of FIG. 2, according to an embodiment of the present disclosure.

FIG. 5 is a perspective view of a portion of the cooling system of the PE system of FIG. 2, according to an embodiment of the present disclosure.

FIG. 6 is a perspective view of a portion of the cooling system of the PE system of FIG. 2, according to an embodiment of the present disclosure.

FIG. 7 is a perspective view of a fan of the cooling system in the PE system of FIG. 2, according to an embodiment of the present disclosure.

FIG. 8 is a perspective view of a base of the transformer of the PE system of FIG. 2, according to an embodiment of the present disclosure.

FIG. 9 is a block diagram of the cooling system of the PE system of FIG. 2, according to an embodiment of the present disclosure.

FIG. 10 is a flow-chart of a method for cooling a power electronic system within an energy container, according to an embodiment of the present disclosure.

The figures depict one embodiment of the presented disclosure for purposes of illustration only. One skilled in the art will readily recognize from the following discussion that alternative embodiments of the structures and methods illustrated herein may be employed without departing from the principles described herein.

### DETAILED DESCRIPTION

Referring now to the drawings, and with specific reference to the depicted example, an energy container 10 is shown, illustrated as a shipping container with a Power Electronic System 100 (“PE system 100”). While the following detailed description describes an exemplary aspect in connection with power electronic components, it should be appreciated that the description applies equally to the use of the present disclosure in other energy systems, including, but not limited to, battery energy storage systems, battery electric machine chargers, Photo-voltaic inverters, fuel cells, electrolyzers, and other energy power systems that require thermal management systems, as well.

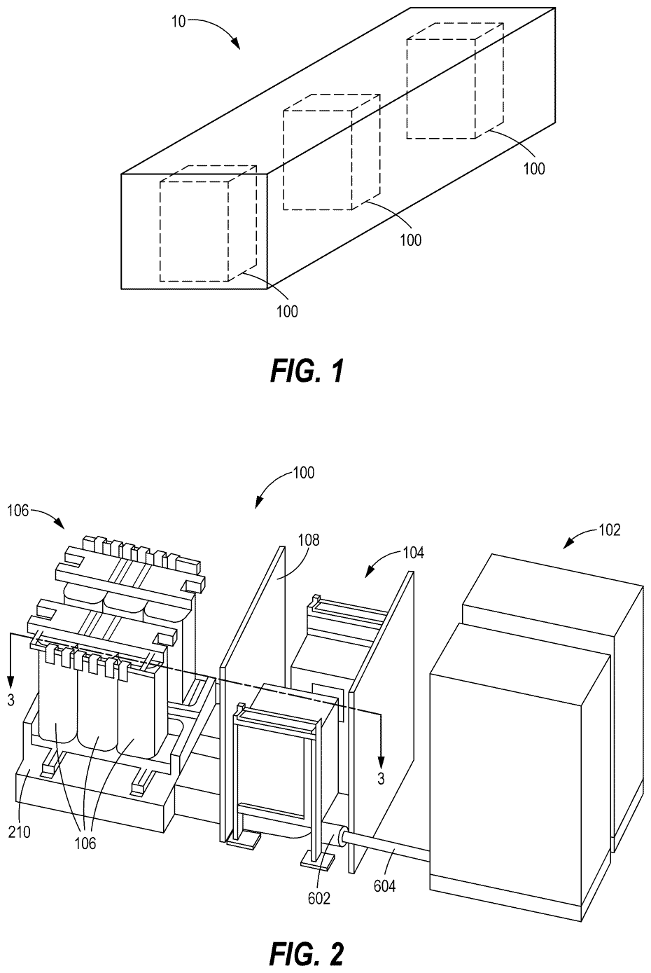

Referring to FIG. 1, a perspective view of an energy container 10 incorporating the PE system 100 is illustrated, according to an embodiment of the present disclosure. The energy container 10 is designed to house and protect the PE system 100, along with associated electronic and cooling components, from external environmental conditions. The energy container 10 may be equipped with ventilation and access points to facilitate the operational efficiency and maintenance of the PE system 100 housed within, as generally known in the arts. The energy container 10 may be further mountable on a variety of work machines, chosen from the group consisting of excavators, cranes, agricultural tractors, mining equipment, drilling rigs, and construction vehicles.

Referring to FIG. 2, a perspective view of the PE system 100 is illustrated, according to an embodiment of the present disclosure. The PE system 100 is designed to efficiently manage thermal loads through integrated cooling solutions, ensuring optimal performance of the power electronic components. The PE System 100 facilitates high-efficiency power conversion processes, crucial for a wide array of applications ranging from renewable energy systems to advanced industrial machinery.

The PE System 100 includes a Power Electronic Module 102 (“PE 102”), a cooling system 104, and plurality of transformers 106. The PE 102 may consist of advanced semiconductor devices such as Insulated Gate Bipolar Transistors (IGBTs) or Metal-Oxide-Semiconductor Field-Effect Transistors (MOSFETs). These components are pivotal in managing and converting electrical power, featuring high switching speeds, and efficiency, which are essential for minimizing energy losses during power conversion processes. The cooling system 104 is included within the PE System 100 to support maintaining the operational integrity of the PEM 102 within an operating temperature range.

The plurality of transformers 106, which serve for voltage regulation and adaptation, ensuring that the electrical power is appropriately modified and distributed for various applications. The plurality of transformers 106 within the PEM 102 help ensure the seamless transition of electrical power from high to low voltage or vice versa, depending on the application's requirements. The plurality of transformers 106 facilitate a broad spectrum of power electronic applications, from intricate industrial machinery operations to the delicate processes involved in renewable energy generation and distribution. Each transformer 106 is designed to handle specific power loads, with a focus on efficiency and durability to withstand the rigors of continuous operation. Moreover, the integration of the cooling system 104 with the plurality of transformers 106 optimizes performance and extends the lifespan of the components by mitigating thermal stress.

A divider 108 is provided between the cooling system 104, the PEM 102, and the plurality of transformers 106, serving as a barrier that ensures distinct operational zones within the Power Electronic System 100. The divider 108, which may be a wall or another form of separator, effectively isolates the heat-sensitive components of the plurality of transformers 106 from the thermal dynamics of the cooling system 104.

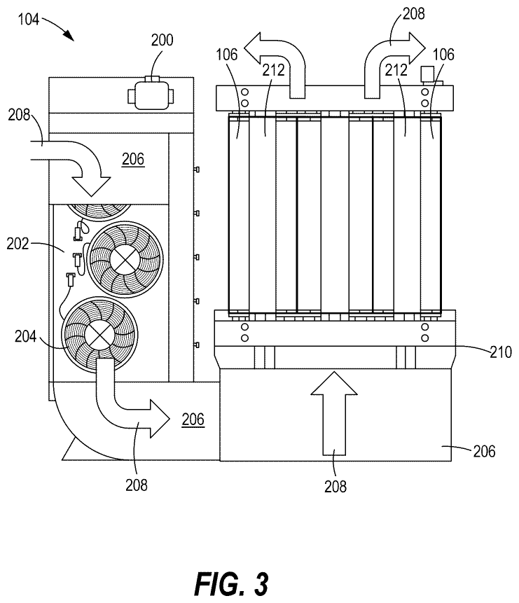

FIG. 3 illustrates a cross-section schematic of the PE System 100 along line 3-3 of FIG. 2, according to an embodiment of the present disclosure. The PE System 100 may include an Electronic Control Module 200 (“ECM 200”) to control the PE 102, cooling system 104, and the plurality of transformers 106. The ECM 200 may manage power flow, monitor system performance, and implement protective measures to prevent overloads or faults. The ECM 200 may utilize sophisticated algorithms and control strategies to optimize the efficiency and reliability of the power conversion process of the PEM 102 and/or the plurality of transformers 106. To support the functionality of the PE System 100, additional subsystems and components may be integrated and in communication with the ECM 200, including sensor arrays for real-time monitoring of electrical and thermal parameters of the PE System 100, and connectivity interfaces for communication with external control systems. These features enable the PE System 100 to operate autonomously while providing operators with critical insights into the performance and health of the PE system 100. The ECM 200 may be configured to interface with adaptive control systems or machine learning algorithms, enabling real-time thermal management optimization based on predictive modeling of thermal loads.

The cooling system 104 includes a heat exchanger 202, a fan 204, and a duct assembly 206. The heat exchanger 202 is provided for dissipating heat generated by the PEM 102 during intense power conversion activities. The heat exchanger 202 may be a radiator, as generally known in the arts. The heat exchanger 202 may be designed with high thermal conductivity materials, such as aluminum or copper, to ensure rapid heat transfer away from the power electronic modules and coolant lines to facilitate the movement of coolant fluid throughout the system, ensuring even distribution of thermal management efforts across the PE System 100. The heat exchanger 202 may employ a fluid-based cooling mechanism, where the coolant absorbs heat from the PEM 102 and the plurality of transformers 106, and transfers it to the heat exchanger 202, where the heat is subsequently expelled into the surrounding environment to support maintaining the PEM 102 and the plurality of transformers 106 at optimal operating temperatures, thereby enhancing their performance and longevity. The cooling system 104 may alternatively employ microchannel heat exchangers or heat pipes, providing improved heat dissipation efficiency in compact form factors due to their enhanced surface area-to-volume ratio.

The coolant lines form a network within the PE System 100, serving as conduits for the coolant fluid, as generally known in the arts. These coolant lines ensure a continuous flow of the coolant fluid from the heat exchanger 202, through the PEM 102 and the plurality of transformers 106, and back to the heat exchanger 202, creating a closed-loop cooling system. The design and placement of the coolant lines are optimized to ensure maximum heat transfer efficiency and to minimize any potential for fluid leakage throughout the PE system 100. In certain embodiments, the cooling system may utilize phase change materials or electrocaloric coolants, offering enhanced thermal management.

The fan 204 is positioned to enhance the cooling process by providing an airflow 208 through the heat exchanger 202 and into the duct assembly 206 for facilitating increased heat exchange and cooling efficiency by cooling warm coolant lines. The operation of the fan 204 may be dynamically controlled, via the ECM 200, to provide cooling as needed while conserving energy. The fan 204 may be a centrifugal fan or any other fan, as generally known in the arts.

The duct assembly 206 directs the airflow 208 within the PE System 100. The duct assembly 206 serves as a pathway for directing the airflow 208 within the cooling system 104 towards the plurality of transformers 106. The duct assembly 206 is designed to channel the airflow 208 from outside, through the heat exchanger 202 towards the plurality of transformers 106, through a transformer base 210, and force the airflow 208 through and away from the PEM 102, where heat generated by the plurality of transformers 106 is expelled. The cooling system 104 is configured to force the airflow 208 against the plurality of transformers 106 to further cool the plurality of transformers 106 by removing additional heat away from the PEM 102 and the plurality of transformers 106, ensuring optimal heat dissipation. Additionally, the plurality of transformers 106 may include a plurality of cores 212 in each of the plurality of transformers 106 to permit the airflow 208 to further enhance cooling of the PEM 100 by forcing the airflow 208 throughout the plurality of cores 212.

The design of the duct assembly 206 may be optimized for space and minimal airflow resistance, ensuring efficient cooling even under high thermal loads. The shape of the duct assembly 206 may be configured in any form that provides forced exhaust air towards the plurality of transformers 106 for effective thermal management, safeguarding the plurality of transformers 106 against thermal stress and contributing to the overall efficiency and reliability of the PE system 100. The duct assembly 206 may be configured in a variety of shapes to accommodate for the design of the energy container 10 and other considerations for various application constraints.

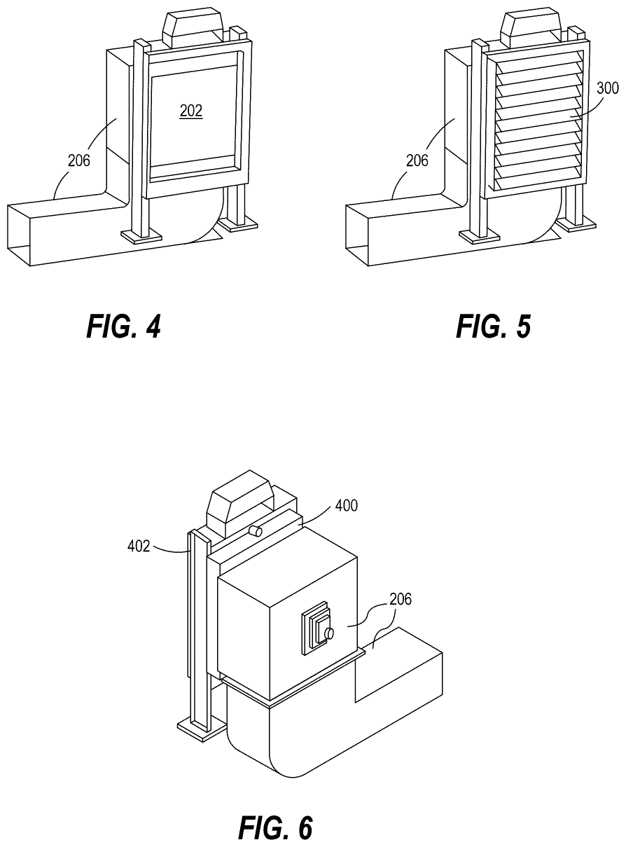

Referring now to FIGS. 4-7, perspective views of components of the cooling system 104 are illustrated, according to an embodiment of the disclosure. FIGS. 4-7 further illustrate the heat exchanger 202, the fan 204, and the duct assembly 206. FIG. 4 illustrates the heat exchanger 202 integrated with the duct assembly 206, according to an embodiment of the disclosure. FIG. 5 illustrates that a louver 300 may be provided to cover the heat exchanger 202 for filtering the airflow 208 to prevent contaminants prior to the airflow entering the duct assembly 206. The louver 300, integrated into the duct assembly 206, allows for regulated air intake.

FIG. 6 further illustrates that the cooling system 104 includes a shroud 400 between the heat exchanger 202 and the duct assembly 206. The shroud 400 may enhance the cooling efficiency by channeling the airflow directly through the heat exchanger 202, preventing bypass and maximizing heat exchange and into the duct assembly 206.

Additionally, a shunt tank 402 may be provided for coolant storage when pressures and temperatures vary within the PE system 100 to prevent coolant fluid leakage. The shunt tank 402, or overflow tank, accommodates the expansion and contraction of the coolant fluid due to temperature fluctuations, preventing overpressure conditions within the system. The tank includes a vent cap to release excess pressure safely and a level indicator for easy monitoring of the coolant volume.

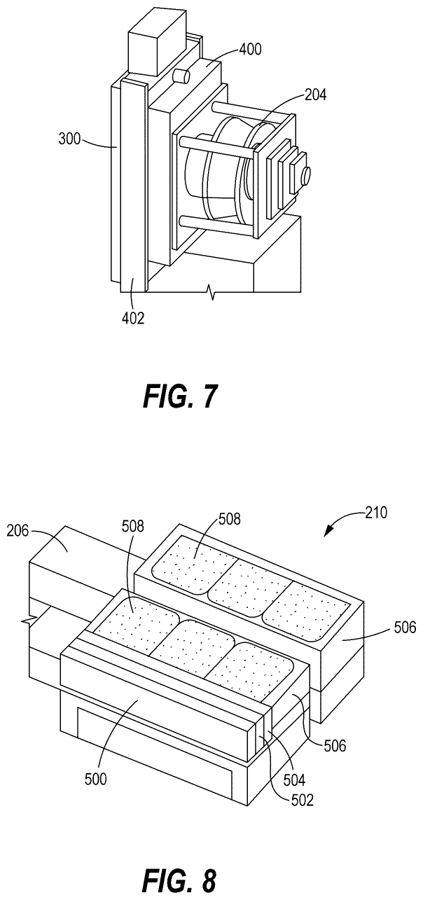

Referring to FIG. 7, a close-up perspective view of a fan 204 in the cooling system 104 is illustrated, according to one embodiment of the disclosure. The fan 204 may be within the duct assembly 206 to draw and direct the airflow 208 into and through the heat exchanger 202, into the duct assembly 206, and out of the transformer base 210 using the forced convection capabilities of the fan 204. The fan 204 may be positioned and designed to ensure effective forced air convection for promoting a sufficient airflow 208 to cool the plurality of transformers 106. The duct assembly 206 may be fabricated from materials such as galvanized steel, aluminum, or high-grade plastic to ensure durability and resistance to corrosion.

A centrifugal fan may be employed as the fan 204 to move the airflow 208 efficiently. A centrifugal fan operates by using the centrifugal force generated by the high-speed rotation of its blades to accelerate air radially outward. The centrifugal design allows for a high-pressure air flow, providing suitable airflow 208 through the duct assembly 206, through the transformer base 210, and forced past the plurality of transformers 106. Depending on specific system requirements, the shape and design of the duct assembly 206, alternative fan configurations such as axial fans, cross flow fans, or bladeless fans may be integrated to optimize airflow and acoustic performance within the cooling system 104.

Additionally, the louver 300, may open or close to regulate the intake of air into the duct assembly 206. The fan 204 may be manually adjustable or automatically controlled by the ECM 200 to adapt to varying thermal conditions within the energy container 10. Alternative types of fans, such as axial fans or bladeless fans, may also be used depending on specific system requirements. These alternative fan types can be easily swapped out or integrated.

Referring to FIG. 8, a perspective view of the transformer base 210 of the PE system 100 of FIG. 1 is illustrated, according to one embodiment of the disclosure. The transformer base 210 may be provided with a sidewall 500, a first baffle 502, a second baffle 504, and a shroud 506. The first baffle 502 and the second baffle 504 are components designed to direct and manage the flow of air or coolant within the system, ensuring optimal thermal regulation and efficiency across the Power Electronic System's cooling architecture. The shroud 506 surrounds a porous jump 508 for further direction and management of the air flow 208 through a porous jump 508. The porous jump 508 permits the airflow 208 to be forced within the plurality of cores 212 and around the plurality of transformers 106 from the duct assembly 206 for effective and uniform cooling of the plurality of transformers 106. The shroud 506 is provided around the plurality of transformers 106 to allow the airflow 208 to maintain an effective forced air convection to cool the plurality of transformers 106 without dissipating outwardly away from the plurality of transformers 106. The shroud 506 may be provided at varying heights to keep the airflow 208 flowing in the same direction after exiting the duct assembly 206 through the porous jump 508.

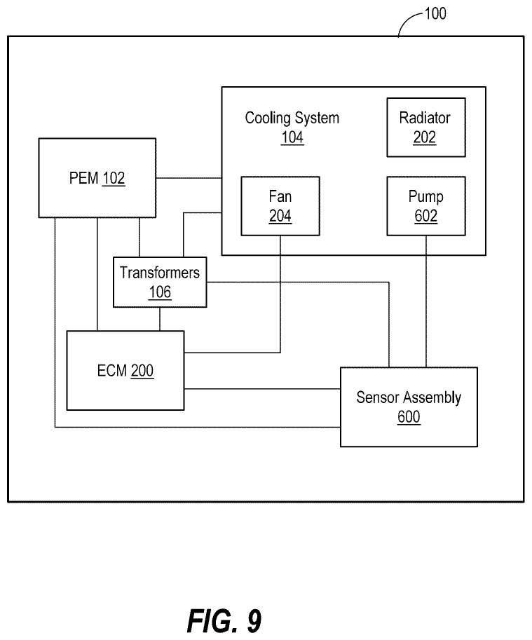

Referring to FIG. 9, a block diagram of PE system 100 is illustrated, according to one embodiment of the disclosure. The PE system 100 is equipped with the ECM 200 designed to maintain the temperature of the PE 102 and the plurality of transformers 106 within a desired temperature range, e.g. between 60-70 degrees C. The ECM 200 communicates with a sensor assembly 600, which may include a plurality of thermocouples, which are positioned proximate or near the PEM 102, the plurality of transformers 106, and/or the cooling system 104. The ECM 200 is also in communication with a pump 602 which transfers coolant throughout a plurality of coolant lines 604. The pump 602 is provided to drive the coolant fluid through the coolant lines 604 and may maintain a consistent flow rate, ensuring that the cooling effect is uniformly distributed across the PEM 102 and the plurality of transformers 106. The pump 602 may be a variable-speed pump configured for modulation or variation of speeds by the ECM 200, as generally known in the arts. The pump 602 may be regulated by the ECM 200 to adapt to varying thermal loads, ensuring that the cooling capacity is aligned with the PE System 100's heat generation.

The ECM 200 continuously receives temperature data from the sensor assembly 600 for real-time monitoring of the temperature of the PEM 102 and the plurality of transformers 106. Upon receiving the temperature data, the ECM 200 compares it with a target temperature. The ECM 200 is configured to keep a target temperature range for the PEM 102 and the plurality of transformers 106. If the temperature falls below or exceeds this range, the ECM 200 activates or deactivates the heat exchanger 202, the fan 204, the pump 602, and any other component in the PE system 100 to bring the temperature back within the desired range, including deactivating the PEM 102 and/or the plurality of transformers 106. The ECM 200 may also continuously receive temperature data from the sensor assembly 600 providing temperatures of coolant lines for monitoring temperatures of the coolant fluid.

Furthermore, the ECM 200 can be programmed to send alerts to a back-office system, remotely via wireless communication. The ECM 200 may be configured to initiate a shutdown of the PE system 100 if the temperature deviates from the set range for an extended period to ensure safety and longevity. Incorporation of smart sensors and IoT capabilities into the cooling system 104 may further enable real-time monitoring, fault detection, and predictive maintenance, ensuring optimal performance and extending the lifespan of power electronic components by the ECM 200.

A power management module may be utilized by the ECM 200 in communication with the PE system 100, the PEM 102, the plurality of transformers 106, and the cooling system 104, regulating power distribution and optimizing energy storage during peak and off-peak periods. The sensor assembly 600 may interface with the power management module, continuously monitoring the energy consumption rates and adjusting the operations of the PE system 100, accordingly.

The integration of the heat exchanger 202 into the structure of the PE system 100 contributes to effective cooling and also to maintaining a compact form factor for the energy container 10. The integrated heat exchangers are positioned to maximize cooling efficiency, thereby reducing the need for a larger and more complex cooling system, enabling a more compact and optimized PE system 100, increasing the ease of installation, and reducing overall costs. A modular design approach for the cooling system 104 could facilitate customizable and scalable thermal management solutions, allowing for easy adaptation to various power electronic system sizes and configurations.

The design facilitated by the integrating the coolant lines of the heat exchanger 202 with the airflow 208 via the duct assembly 206 improves space utilization, thereby increasing overall power generation capacity.

An external interface port may be provided on the energy container 10, facilitating easy connection to external power grids or other energy-consuming systems, allowing the PE system 100 to function as a primary or backup power source.

To further safeguard the PE system 100 from potential moisture-related damage, a dehumidifier may be integrated within the duct assembly 206 of the cooling system 104. The dehumidifier is designed to remove excess moisture from the airflow 208 before it reaches the plurality of transformers 106, thereby preventing condensation that could lead to electrical failures or corrosion. This addition is useful in environments where the ambient air contains high levels of humidity which, when cooled, could condense on critical components of the PEM 102 and the plurality of transformers 106. The dehumidifier ensures that the air supplied to the cooling system remains dry, thus maintaining the operational integrity and extending the lifespan of the plurality of transformers 106 within the PEM system 100.

During shutdown procedures, the ECM 200 may initiate a cooling protocol to gradually bring the temperature of the PEM 102 and/or the plurality of transformers 106 down to a safe level for system shutdown. This ensures that no thermal stress is induced on the PEM 102 or the plurality of transformers 106, preserving its longevity.

### Industrial Applicability

In operation, the present disclosure may find applicability in numerous sectors, including but not limited to, renewable energy sources, emergency power backups, commercial enterprises, and portable power units. Particularly, the advanced cooling mechanisms and methodologies outlined in this disclosure are suitable for use in photovoltaic energy configurations for diverse machinery, stationary energy setups, contingency power reserves, and power grid systems. Specifically, the thermal management and cooling systems and methods of the present disclosure may be used in energy systems for various work machines, as well as stationary power systems, emergency backup power systems, and grid-balancing power systems. While the foregoing detailed description is made with specific reference to stationary power systems, it should be understood that its teachings may also be applied to other power generation applications.

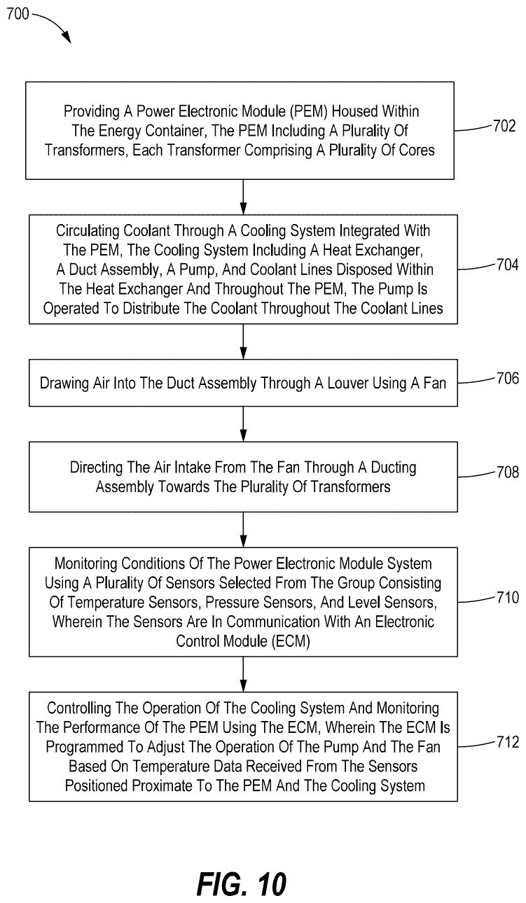

Now referring to FIG. 10, a method 700 for cooling the PE system 100 within the energy container 10 is illustrated, according to an embodiment. The method 700 is suited for applications requiring efficient thermal management of power electronic components, such as in renewable energy systems, electric vehicle charging stations, fuel cell systems, and various industrial machinery, ensuring their optimal performance and longevity.

In a step 702, the method 700 begins with providing the PEM 102 and the plurality of transformers 106 housed within the energy container 10. Each of the plurality of transformers 106 comprising a plurality of cores 212.

In a step 704, the method 700 includes circulating coolant through the cooling system 104 integrated within the PE system 100. The cooling system 104 comprising a heat exchanger 202, a duct assembly 206, a pump 602, and coolant lines. The pump 602 is tasked with distributing the coolant throughout the PE system 100, ensuring even thermal management across all components.

In a step 706, air is drawn into the duct assembly 206 through a louver 300 using a fan 204. The louver 300 serves the dual purpose of regulating air intake and preventing contaminants from entering the duct assembly 206, thus safeguarding the internal components from potential damage.

In a step 708, the air intake is directed from the fan 204 through the duct assembly 206 towards the plurality of transformers 106. The duct assembly 206 is designed to optimize the airflow 208, ensuring efficient heat dissipation from the plurality of transformers 106 and maintaining them within desired operational temperatures.

In a step 710, conditions of the PE system 100 are continuously monitored using the sensor assembly 600, including temperature sensors, pressure sensors, and level sensors. The sensor assembly 600 is in communication with ECM 200, enabling real-time tracking of performance and environmental conditions during operation of the PE system 100.

In a step 712, the operation of the cooling system 104 is controlled based on the performance and monitoring of the PEM 102 and the plurality of transformers 106 by the ECM 200. The ECM 200 may be programmed to dynamically adjust the operational controls of the heat exchanger 202, the pump 602, and the fan 204 based on data received from the sensor assembly 600, ensuring that the PEM 102 and the plurality of transformers 106 operates within the optimal temperature range.

The energy container 10, as depicted in FIG. 1, is designed to house the PE system 100 securely, protecting it from external environmental conditions. This container may include ventilation and access points to facilitate maintenance and operational efficiency.

The cooling system 104's heat exchanger 202 may be a radiator may be made from high thermal conductivity materials such as aluminum or copper, as shown in FIG. 3, to facilitate rapid heat transfer. The coolant lines create a closed-loop system, ensuring continuous coolant flow and efficient heat dissipation.

The fan 204, provided as a centrifugal fan, enhances cooling by providing a high-pressure airflow 208 through the heat exchanger 202 and into the duct assembly 206, as depicted in FIG. 3. This forced convection is critical for maintaining the plurality of transformers 106 at optimal operating temperatures.

The ECM 200, illustrated in FIG. 9, manages power flow, monitors system performance, and implements protective measures. In addition, the ECM 200 may be configured to communicate with external control systems and back-office system through a communication network, providing operators with insights into the performance and health of the PE system 100.

The integration of the cooling system within the energy container 10 not only ensures effective thermal management but also contributes to a compact system design. This integration enhances space utilization and power generation capacity, as discussed in the detailed description. An external interface port may be provided on the energy container 10, allowing for easy connection to external power grids or energy-consuming systems. This enables the PE system 100 to function as a primary or backup power source, offering flexibility across various application scenarios. The energy container 10 also acts to protect from incidents of arc flash from the plurality of transformers 106 in case of malfunction, and prevents subsystems and external entities or persons from hazard.

By recirculating air with the plurality of transformers 106 and the liquid coolant with the PE 102, this approach minimizes the need for extensive external cooling infrastructure, leading to a more compact and efficient setup. This integration optimizes the operational performance of the PE system 100 but also contributes to a reduction in overall system size by recycling exhaust air from radiators and other heat exchangers for cooling.

In shutdown procedures, the ECM 200 initiates a cooling protocol to gradually reduce the temperature of the PEM 102 and/or the plurality of transformers 106 to a safe level, ensuring the longevity and preventing thermal stress on the components of the PE system 100.

From the foregoing, it can be seen that the technology disclosed herein has industrial applicability in a variety of settings and environments requiring dependable and effective thermal regulation during electricity or battery production via power electronic systems, photovoltaic systems, renewable energy systems, emergency power backups, and industrial energy production systems.

What is claimed is:

1. A cooling system for a power electronic system comprising:
a heat exchanger;
coolant lines disposed within the heat exchanger and throughout the power electronic system;
a pump configured to distribute coolant throughout the coolant lines;
a fan configured for air intake through the heat exchanger to cool the coolant lines; and
a duct assembly configured to direct the air intake from the fan towards the power electronic system.

2. The cooling system of claim 1, the power electronic system including a power electronic module (PEM) and a plurality of transformers, and the duct assembly configured to direct the air intake from the fan towards the PEM.

3. The cooling system of claim 2, wherein the plurality of transformers includes a plurality of cores in each transformer to receive exhaust air from the cooling system.

4. The cooling system of claim 2, further comprising an electronic control module (ECM) configured to control the operation of the cooling system and to monitor a performance of the PEM, and a plurality of sensors in communication with the ECM, the plurality of sensors are selected from a group consisting of temperature sensors, pressure sensors, and level sensors, configured to monitor conditions of the power electronic system.

5. The cooling system of claim 2, the pump is a variable-speed pump, and the pump is modulated based on thermal load detected within the power electronic system.

6. The cooling system of claim 2, wherein the heat exchanger is a radiator, and the fan is a centrifugal fan designed to provide high-pressure airflow through the heat exchanger and the duct assembly.

7. The cooling system of claim 2, further comprising a louver positioned to cover the heat exchanger, configured to filter the air intake to prevent contaminants from entering the duct assembly.

8. The cooling system of claim 2, further comprising a shroud fluidly connected to the duct assembly and disposed around the PEM to channel airflow directly towards the plurality of transformers.

9. The cooling system of claim 2, further comprising a dehumidifier in the duct assembly.

10. An energy container for housing a power electronic system, the energy container comprising:
a container;
a power electronic module (PEM);
a plurality of transformers; and
a cooling system including:
a heat exchanger;
coolant lines disposed within the heat exchanger and throughout the power electronic system;
a pump configured to distribute coolant throughout the coolant lines;
a fan configured for air intake through the heat exchanger to cool the coolant lines; and
a duct assembly configured to direct the air intake from the fan towards the plurality of transformers.

11. The energy container of claim 10, wherein the plurality of transformers includes a plurality of cores in each transformer.

12. The energy container of claim 10, further comprising an electronic control module (ECM) configured to control the operation of the cooling system and to monitor a performance of the PEM, and a plurality of sensors in communication with the ECM, the plurality of sensors are selected from a group consisting of temperature sensors, pressure sensors, and level sensors, configured to monitor conditions of the power electronic system, and the pump is a variable-speed pump modulated based on thermal loads detected within the power electronic system.

13. The energy container of claim 10, wherein the heat exchanger is a radiator, and the fan is a centrifugal fan designed to provide high-pressure airflow through the heat exchanger and the duct assembly.

14. The energy container of claim 10, further comprising a louver positioned to cover the heat exchanger, configured to filter the air intake to prevent contaminants from entering the cooling system.

15. The energy container of claim 10, further comprising a dehumidifier in the duct assembly.

16. The energy container of claim 10, further comprising a shroud fluidly connected to the duct assembly and disposed around the PEM to channel airflow directly towards the plurality of transformers.

17. The energy container of claim 12, wherein the ECM is programmed to adjust the operation of the pump and the fan based on temperature data received from the sensors positioned proximate to the PEM and the cooling system.

18. The energy container of claim 10, wherein the energy container is further mountable on a variety of work machines, chosen from the group consisting of excavators, cranes, agricultural tractors, mining equipment, drilling rigs, and construction vehicles.

19. A method for cooling a power electronic system within an energy container, comprising:
providing a power electronic module (PEM) housed within the energy container, the PEM including a plurality of transformers, each transformer comprising a plurality of cores;
circulating coolant through a cooling system integrated with the PEM, the cooling system including a heat exchanger, a duct assembly, a pump, and coolant lines disposed within the heat exchanger and throughout the PEM, the pump is operated to distribute a coolant throughout the coolant lines;
drawing air into the duct assembly through a louver using a fan; and
directing intake of air from the fan through the duct assembly towards the plurality of transformers.

20. The method of claim 19, further comprising:
monitoring conditions of the power electronic system using a plurality of sensors selected from a group consisting of temperature sensors, pressure sensors, and level sensors, wherein the sensors are in communication with an electronic control module (ECM); and
controlling the operation of the cooling system and monitoring a performance of the PEM using the ECM, wherein the ECM is programmed to adjust the operation of the pump and the fan based on temperature data received from the sensors positioned proximate to the PEM and the cooling system.
